(19) United States
(12) Patent Application Publication
(10) Pub. No.: US 2025/0012606 A1
(43) Pub. Date: Jan. 9, 2025

(54) DISTANCE MEASURING DEVICE, DISTANCE MEASURING METHOD, BONDING APPARATUS, AND BONDING METHOD

(71) Applicant: Tokyo Electron Limited, Tokyo (JP)

(72) Inventor: Tetsuya Maki, Koshi City (JP)

(21) Appl. No.: 18/764,474

(22) Filed: Jul. 5, 2024

(30) Foreign Application Priority Data
Jul. 6, 2023 (JP) 2023-111490

(51) Int. Cl. G01D 5/24; H01L 21/67

(52) U.S. Cl. CPC G01D 5/24; H01L 21/67259

(57) ABSTRACT

A distance measuring device includes a first member disposed to face a measurement target, which is a conductor or a semiconductor, in a non-contact manner; and an electrostatic capacitance sensor provided at the first member, and configured to measure a distance to the measurement target. The first member is formed of a conductive member, and the electrostatic capacitance sensor is grounded via the first member.

### CROSS-REFERENCE TO RELATED APPLICATION

This application claims the benefit of Japanese Patent Application No. 2023-111490 filed on Jul. 6, 2023, the entire disclosures of which are incorporated herein by reference.

### TECHNICAL FIELD

The various aspects and embodiments described herein pertain generally to a distance measuring device, a distance measuring method, a bonding apparatus, and a bonding method.

### BACKGROUND

Conventionally, there is known a bonding apparatus that bonds substrates such as semiconductor wafers together (see Patent Document 1).
Patent Document 1: Japanese Patent Laid-open Publication No. 2018-147944

### SUMMARY

In one exemplary embodiment, a distance measuring device includes a first member disposed to face a measurement target, which is a conductor or a semiconductor, in a non-contact manner; and an electrostatic capacitance sensor provided at the first member, and configured to measure a distance to the measurement target. The first member is formed of a conductive member, and the electrostatic capacitance sensor is grounded via the first member.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic plan view illustrating a configuration of a bonding system according to an exemplary embodiment;

FIG. 2 is a schematic side view of an upper wafer and a lower wafer according to the exemplary embodiment;

FIG. 3 is a schematic plan view illustrating a configuration of a bonding apparatus according to the exemplary embodiment;

FIG. 4 is a schematic side view illustrating the configuration of the bonding apparatus according to the exemplary embodiment;

FIG. 5 is a schematic diagram illustrating an upper chuck and a lower chuck according to the exemplary embodiment;

FIG. 6 is a schematic diagram illustrating the upper chuck seen from below;

FIG. 7 is an enlarged schematic diagram of a main body of the upper chuck, sensors, and the upper wafer according to the exemplary embodiment;

FIG. 8 is a graph showing variations of measurement values of the sensors in FIG. 7; and

FIG. 9 is a flowchart illustrating a sequence of a processing performed by the bonding system according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, embodiments for a distance measuring device, a distance measuring method, a bonding apparatus, and a bonding method according to the present disclosure (hereinafter, referred to as “exemplary embodiments”) will be described in detail with reference to the accompanying drawings. Further, it should be noted that the present disclosure is not limited by the exemplary embodiments. Furthermore, unless processing contents are contradictory, the various exemplary embodiments can be appropriately combined. In addition, in the various exemplary embodiments to be described below, same parts will be assigned same reference numerals, and redundant description will be omitted.

Further, in the following exemplary embodiments, expressions such as “constant,” “perpendicular,” “vertical” and “parallel” may be used. These expressions, however, do not imply strictly “constant”, “perpendicular,” “vertical” and “parallel”. That is, these expressions allow some tolerable errors in, for example, manufacturing accuracy, installation accuracy, or the like.

Moreover, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as “0 direction.”

When a center of one substrate is pressed into contact with the other substrate in order to bond the substrates to each other by using an intermolecular force, a bonding wave is generated, whereby a bonding region gets expanded from the centers of the substrates toward outer peripheries thereof. In a bonding apparatus, a processing of measuring the progress of the bonding wave may be performed. For example, through the use of a sensor provided at a holder configured to attract and hold the substrate from above, the progress of the bonding wave is measured by measuring a distance from this holder to the substrate (measurement target). Accurate measurement of the progress of the bonding wave leads to improved bonding precision of the substrates.

Here, as a way to accurately measure the progress of the bonding wave, there may be considered a method of increasing the number of sensors used to measure the distance between the holder and the substrate. For example, by using an electrostatic capacitance sensor that is smaller than an optical displacement meter or the like, the number of the sensors used to measure the distance to the substrate can be increased.

When using the electrostatic capacitance sensor, a measurement target is usually a conductor, and the electrostatic capacitance sensor and the measurement target are electrically connected. However, it has been difficult to meet these requirements in the bonding apparatus configured to bond the substrates together. In this regard, there is a demand for a technique that enables distance measurement using the electrostatic capacitance sensor even when there is no electrical conduction between the electrostatic capacitance sensor and the measurement target.

In addition, this technique is expected to be applied to other devices as well without being limited to the bonding apparatus. Although the following description will be provided for an embodiment where a distance measuring device and a distance measuring method according to the present disclosure are applied to the bonding apparatus, the distance measuring device and the distance measuring method according to the present disclosure is also applicable to various other devices.

### <Configuration of Bonding System>

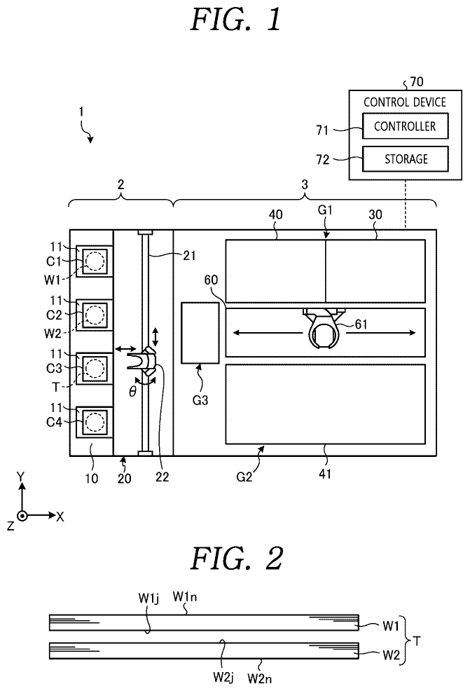

First, a configuration of a bonding system 1 according to an exemplary embodiment will be explained with reference to FIG. 1 and FIG. 2. FIG. 1 is a schematic plan view illustrating a configuration of the bonding system 1 according to the exemplary embodiment. FIG. 2 is a schematic side view of an upper wafer W1 and a lower wafer W2 according to the exemplary embodiment.

The bonding system 1 shown in FIG. 1 is configured to bond a first substrate W1 and a second substrate W2 to form a combined wafer T.

The first substrate W1 and the second substrate W2 are semiconductor substrates, such as, but not limited to, silicon wafers or compound semiconductor wafers. The first substrate W1 and the second substrate W2 have approximately the same diameter.

Hereinafter, the first substrate W1 will be referred to as “upper wafer W1,” and the second substrate W2 will be referred to as “lower wafer W2.” That is, the upper wafer W1 is an example of a first substrate, and the lower wafer W2 is an example of a second substrate. Further, the upper wafer W1 and lower wafer W2 will sometimes be collectively referred to “wafer W.”

In addition, hereinafter, as illustrated in FIG. 2, among plate surfaces of the upper wafer W1, the plate surface to be bonded to the lower wafer W2 will be referred to as “bonding surface W1j,” and the plate surface opposite to the bonding surface W1j will be referred to as “non-bonding surface W1n.” Likewise, among plate surfaces of the lower wafer W2, the plate surface to be bonded to the upper wafer W1 will be referred to as “bonding surface W2j,” and the plate surface opposite to the bonding surface W2j will be referred to as “non-bonding surface W2n.”

As depicted in FIG. 1, the bonding system 1 is equipped with a carry-in/out station 2 and a processing station 3. The carry-in/out station 2 and the processing station 3 are arranged in this order along the positive X-axis direction. Also, the carry-in/out station 2 and the processing station 3 are connected as one body.

The carry-in/out station 2 includes a placement table 10 and a transfer section 20. The placement table 10 is equipped with a multiple number of placement plates 11. Provided on the placement plates 11 are cassettes C1, C2 and C3 each of which accommodates therein a plurality of (e.g., 25 sheets of) substrates horizontally. For example, the cassette C1 accommodates therein upper wafers W1; the cassette C2, lower wafers W2; and the cassettes C3, combined wafers T.

The transfer section 20 is provided adjacent to the positive X-axis side of the placement table 10. This transfer section 20 is provided with a transfer path 21 extending in the Y-axis direction and a transfer device 22 configured to be movable along this transfer path 21.

The transfer device 22 is configured to be movable in the X-axis direction as well as in the Y-axis direction and pivotable around the Z-axis. The transfer device 22 serves to transfer the upper wafers W1, the lower wafers W2, and the combined wafers T between the cassettes C1 to C3 placed on the placement plates 11 and a third processing block G3 of the processing station 3 to be described later.

Further, the number of the cassettes C1 to C3 disposed on the placement plates 11 is not limited to the shown example. Moreover, in addition to the cassettes C1, C2, and C3, a cassette for collecting a defective substrate may be disposed on the placement plate 11.

The processing station 3 has a plurality of processing blocks equipped with various types of devices, for example, three processing blocks G1, G2 and G3. For example, the first processing block G1 is provided on the front side (negative Y-axis side of FIG. 1) of the processing station 3, and the second processing block G2 is provided on the rear side (positive Y-axis side of FIG. 1) of the processing station 3. Further, the third processing block G3 is provided on the carry-in/out station 2 side (negative X-axis side of FIG. 1) of the processing station 3.

The first processing block G1 is equipped with a surface modifying apparatus 30 configured to modify the bonding surface W1j of the upper wafer W1 and the bonding surface W2j of the lower wafer W2. The surfacy modifying apparatus 30 cuts a SiO₂ bond in the bonding surfaces W1j and W2j of the upper and lower wafers W1 and W2 to form a single bond of SiO, thus modifying the bonding surfaces W1j and W2j so that they can be easily hydrophilized afterwards.

Further, a surface hydrophilizing apparatus 40 is disposed in the first processing block G1. The surface hydrophilizing apparatus 40 is configured to hydrophilize the bonding surfaces W1j and W2j of the upper and lower wafers W1 and W2 with, for example, pure water, and also serves to clean the bonding surfaces W1j and W2j.

In the surface hydrophilizing apparatus 40, while rotating the upper wafer W1 or the lower wafer W2 held by, for example, a spin chuck, the pure water is supplied onto the upper wafer W1 or the lower wafer W2. Accordingly, the pure water supplied onto the upper wafer W1 or the lower wafer W2 is diffused on the bonding surface W1j of the upper wafer W1 or the bonding surface W2j of the lower wafer W2, so that the bonding surfaces W1j and W2j are hydrophilized.

In the present exemplary embodiment, the surface modifying apparatus 30 and the surface hydrophilizing apparatus 40 are arranged horizontally. However, the surface hydrophilizing apparatus 40 may be stacked on or under the surface modifying apparatus 30.

The second processing block G2 includes a bonding apparatus 41. The bonding apparatus 41 is configured to bond the hydrophilized upper and lower wafers W1 and W2 by an intermolecular force. Details of this bonding apparatus 41 will be described later.

The third processing block G3 is equipped with a transition (TRS) device (not shown) for the upper wafer W1, the lower wafer W2, and the combined wafer T.

Further, as depicted in FIG. 1, a transfer section 60 is formed in an area surrounded by the first processing block G1, the second processing block G2, and the third processing block G3. A transfer device 61 is disposed in the transfer section 60. The transfer device 61 has a transfer arm configured to be movable in a vertical direction and a horizontal direction and pivotable around a vertical axis, for example.

This transfer device 61 is moved within the transfer section 60 to transfer the upper wafer W1, the lower wafer W2, and the combined wafer T to devices within the first processing block G1, the second processing block G2, and the third processing block G3 adjacent to the transfer section 60.

Further, the bonding system 1 is equipped with a control device 70. The control device 70 is configured to control an operation of the bonding system 1. This control device 70 is, for example, a computer, and has a controller 71 and a storage 72. The controller 71 includes a microcomputer having a central processing unit (CPU), a read only memory (ROM), a random access memory (RAM), input/output ports, etc., and various types of circuits. The CPU of such a microcomputer reads and executes a program stored in the ROM, thus implementing a control to be described later. Further, the storage 72 is implemented by, by way of non-limiting example, a semiconductor memory element such as a RAM or a flash memory, or a storage device such as a hard disk or an optical disk.

Additionally, such a program may have been recorded on a computer-readable recording medium, and may be installed from the recording medium into the storage 72 of the control device 70. The computer-readable recording medium may be, by way of non-limiting example, a hard disk (HD), a flexible disk (FD), a compact disk (CD), a magnet optical disk (MO), a memory card, or the like.

### <Configuration of Bonding Apparatus>

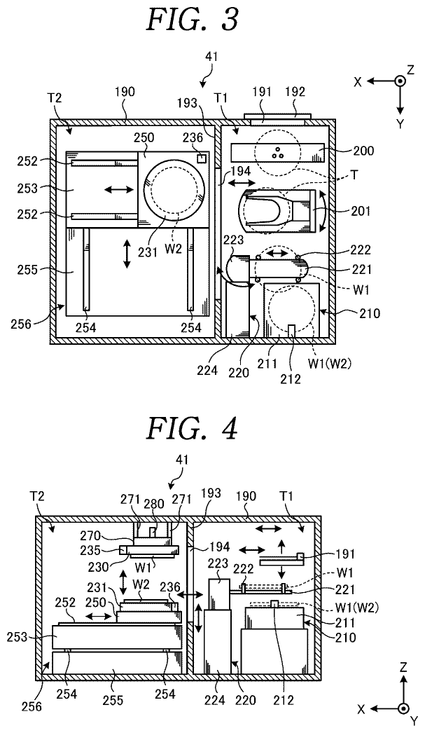

Now, a configuration of the bonding apparatus 41 will be explained with reference to FIG. 3 and FIG. 4. FIG. 3 is a schematic plan view illustrating the configuration of the bonding apparatus 41 according to the exemplary embodiment, and FIG. 4 is a schematic side view showing the configuration of the bonding apparatus 41 according to the exemplary embodiment.

As depicted in FIG. 3, the bonding apparatus 41 is equipped with a processing vessel 190 having a hermetically sealable inside. A carry-in/out opening 191 for the upper wafer W1, the lower wafer W2, and the combined wafer T is formed in a side surface of the processing vessel 190 on the side of the transfer section 60, and an opening/closing shutter 192 is provided at this carry-in/out opening 191.

The inside of the processing vessel 190 is partitioned into a transfer section T1 and a processing section T2 by an inner wall 193. The carry-in/out opening 191 described above is formed in the side surface of the processing vessel 190 in the transfer section T1. Further, the inner wall 193 is also provided with a carry-in/out opening 194 for the upper wafer W1, the lower wafer W2, and the combined wafer T.

In the transfer section T1, a transition device 200, a substrate transfer mechanism 201, an inverting mechanism 220, and a position adjusting mechanism 210 are arranged in this order from the carry-in/out opening 191 side, for example.

The transition device 200 temporarily places therein the upper wafer W1, the lower wafer W2, and the combined wafer T. The transition device 200 is formed in, for example, two levels, and is thus capable of placing therein any two of the upper wafer W1, the lower wafer W2, and the combined wafer T at the same time.

The substrate transfer mechanism 201 has a transfer arm configured to be movable in a vertical direction (Z-axis direction) and horizontal directions (X-axis direction and Y-axis direction) and pivotable around a vertical axis (θ direction), for example. The substrate transfer mechanism 201 is capable of transferring the upper wafer W1, the lower wafer W2, and the combined wafer T within the transfer section T1 or between the transfer section T1 and the processing section T2.

The position adjusting mechanism 210 is configured to adjust the direction of the upper wafer W1 and the lower wafer W2 in a horizontal direction. Specifically, the position adjusting mechanism 210 includes a base 211 equipped with a holder (not shown) configured to hold and rotate the upper and lower wafers W1 and W2, and a detector 212 configured to detect the positions of notches of the upper wafer W1 and the lower wafer W2. By detecting the positions of the notches of the upper wafer W1 and the lower wafer W2 through the use of the detector 212 while rotating the upper wafer W1 and the lower wafer W2 held by the base 211, the position adjusting mechanism 210 adjusts the positions of the notches. Accordingly, the direction of the upper wafer W1 and the lower wafer W2 in the horizontal direction is adjusted.

The inverting mechanism 220 is configured to invert front and rear surfaces of the upper wafer W1. Specifically, the inverting mechanism 220 has a holding arm 221 configured to hold the upper wafer W1. The holding arm 221 extends in a horizontal direction (X-axis direction). Further, the holding arm 221 is provided with holding members 222 for holding the upper wafer W1 at, for example, four positions thereon.

The holding arm 221 is supported by a driver 223 equipped with, for example, a motor. The holding arm 221 is rotatable around a horizontal axis by this driver 223. Further, the holding arm 221 is also rotatable about the driver 223 and movable in a horizontal direction (X-axis direction). Below the driver 223, another driver (not shown) provided with, for example, a motor is provided. The driver 223 can be moved in a vertical direction by this other driver along a supporting column 224 that extends in the vertical direction.

In this way, the upper wafer W1 held by the holding members 222 can be rotated around the horizontal axis by the driver 223, and can also be moved in the vertical and horizontal directions. Further, the upper wafer W1 held by the holding members 222 can be moved between the position adjusting mechanism 210 and an upper chuck 230 to be described later by being rotated about the driver 223.

Provided in the processing section T2 are the upper chuck 230 configured to attract and hold a top surface (non-bonding surface W1n) of the upper wafer W1 from above and a lower chuck 231 configured to attract and hold a bottom surface (non-bonding surface W2n) of the lower wafer W2 from below. The lower chuck 231 is disposed below the upper chuck 230, and is configured to face the upper chuck 230. The upper chuck 230 and the lower chuck 231 are, for example, vacuum chucks. The upper chuck 230 is an example of a first holder, and the lower chuck 231 is an example of a second holder. Specific configurations of the upper chuck 230 and the lower chuck 231 will be described later.

As depicted in FIG. 4, the upper chuck 230 is supported by a supporting member 270 provided above the upper chuck 230. The supporting member 270 is fixed to a ceiling surface of the processing vessel 190 with, for example, a plurality of supporting columns 271 therebetween.

An upper imaging device 235 configured to image a top surface (bonding surface W2j) of the lower wafer W2 held by the lower chuck 231 is provided at a lateral side of the upper chuck 230. The upper imaging device 235 may be, for example, a CCD camera.

The lower chuck 231 is supported by a first mover 250 disposed below the lower chuck 231. The first mover 250 serves to move the lower chuck 231 in a horizontal direction (X-axis direction) as will be described later. Further, the first mover 250 is configured to be able to move the lower chuck 231 in a vertical direction and to rotate the lower chuck 231 around a vertical axis.

The first mover 250 is provided with a lower imaging device 236 configured to image a bottom surface (bonding surface W1j) of the first substrate W1 held by the upper chuck 230. The lower imaging device 236 may be, for example, a CCD camera. The lower imaging device 236 is an example of an imaging device.

The first mover 250 is mounted to a pair of rails 252. The rails 252 are disposed at a bottom surface side of the first mover 250, and is elongated in a horizontal direction (X-axis direction). The first mover 250 is configured to be movable along the rails 252.

The pair of rails 252 are mounted to a second mover 253. The second mover 253 is mounted to a pair of rails 254. The rails 254 are provided on a bottom surface side of the second mover 253, and is elongated in a horizontal direction (Y-axis direction). The second mover 253 is configured to be movable in the horizontal direction (Y-axis direction) along the rails 254. Further, the pair of rails 254 are disposed on a placement table 255 which is provided on a bottom surface of the processing vessel 190.

The first mover 250, the second mover 253, and the like constitute a position aligning device 256. The position aligning device 256 moves the lower chuck 231 in the X-axis direction, the Y-axis direction, and the θ direction, thus allowing the upper wafer W1 held by the upper chuck 230 and the lower wafer W2 held by the lower chuck 231 to be aligned in the horizontal direction. In addition, the position aligning device 256 moves the lower chuck 231 in the Z-axis direction as well, thus allowing the upper wafer W1 held by the upper chuck 230 and the lower wafer W2 held by the lower chuck 231 to be aligned in the vertical direction as well.

Here, although the lower chuck 231 is moved in the X-axis direction, the Y-axis direction, and the θ direction, the position aligning device 256 may be configured to move the lower chuck 231 in the X-axis direction and the Y-axis direction and move the upper chuck 230 in the θ direction, for example. Further, although the lower chuck 231 is moved in the Z-axis direction in the present exemplary embodiment, the position aligning device 256 may be configured to move the upper chuck 230 in the Z-axis direction, for example.

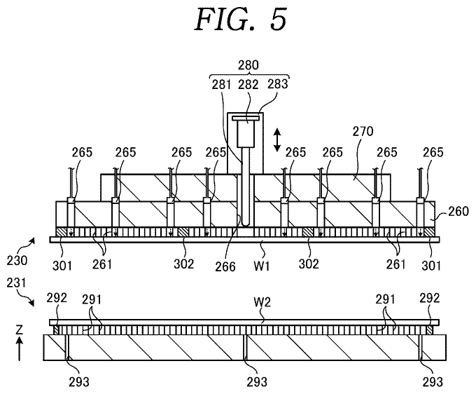

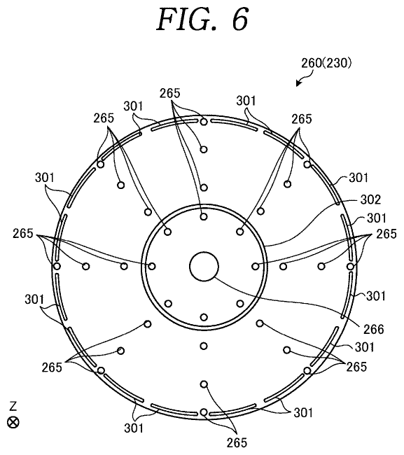

Now, the configurations of the upper chuck 230 and the lower chuck 231 will be described with reference to FIG. 5. FIG. 5 is a schematic diagram illustrating the configurations of the upper chuck 230 and the lower chuck 231 according to the exemplary embodiment. FIG. 6 is a schematic diagram illustrating the upper chuck 230 seen from below.

As shown in FIG. 5, the upper chuck 230 has a main body 260 (an example of a first member). The main body 260 is supported by the supporting member 270. The main body 260 is disposed to face the upper wafer W1 in a non-contact manner. A bottom surface of the main body 260 is a facing surface that faces the bottom surface (non-bonding surface W1n) of the upper wafer W1. A through hole 266 is formed through the supporting member 270 and the main body 260 in a vertical direction. The position of the through hole 266 corresponds to the center of the upper wafer W1 attracted to and held by the upper chuck 230. A pressing pin 281 of a striker 280 is inserted through the through hole 266.

The striker 280 is disposed on a top surface of the supporting member 270, and is equipped with the pressing pin 281, an actuator 282, and a linearly moving mechanism 283. The pressing pin 281 is a cylindrical member extending in the vertical direction, and is supported by the actuator 282. The striker 280 is an example of a pressing member.

The actuator 282 is configured to generate a constant pressure in a certain direction (here, a vertically downward direction) by air supplied from, for example, an electro-pneumatic regulator (not shown). By the air supplied from the electro-pneumatic regulator, the actuator 282 comes into contact with a central portion of the upper wafer W1 and is capable of controlling a pressing load applied to the central portion of the upper wafer W1. Further, a leading end of the actuator 282 is movable up and down in the vertical direction through the through hole 266 by the air from the electro-pneumatic regulator.

The actuator 282 is supported by the linearly moving mechanism 283. The linearly moving mechanism 283 is configured to move the actuator 282 along the vertical direction by a driver having, for example, a motor embedded therein.

The striker 280 is configured as described above, and controls the movement of the actuator 282 by the linearly moving mechanism 283 and controls the pressing load on the upper wafer W1 from the pressing pin 281 by the actuator 282. Through these operations, the striker 280 presses the central portion of the upper wafer W1 held by the upper chuck 230 into contact with the lower wafer W2.

A plurality of pins 261 to be brought into contact with the top surface (non-bonding surface W1n) of the upper wafer W1 is provided on a bottom surface of the main body 260. Each of these pins 261 has a diameter of, e.g., 0.1 mm to 1 mm and a height of several tens of μm to several hundreds of μm. The plurality of pins 261 are evenly arranged at a distance of, e.g., 2 mm.

The upper chuck 230 is provided with a plurality of attraction portions for attracting the upper wafer W1 in some of the regions where the plurality of pins 261 are provided. Specifically, a plurality of outer attraction portions 301 and an inner attraction portion 302 are provided in the bottom surface of the main body 260 of the upper chuck 230 to attract the upper wafer W1 by evacuation. The plurality of outer attraction portions 301 and the inner attraction portion 302 have arc-shaped attraction regions when viewed from the top. The outer attraction portions 301 and the inner attraction portion 302 have the same height as the pins 261.

The plurality of outer attraction portions 301 are arranged at an outer periphery of the main body 260 along a circumferential direction thereof, as illustrated in FIG. 6. These outer attraction portions 301 are connected to a non-illustrated suction device such as a vacuum pump, and attract an outer periphery of the upper wafer W1 by a suction force generated by the suction device.

The inner attraction portion 302 is arranged at a diametrically inner side of the main body 260 than the outer attraction portions 301 along the circumferential direction. The inner attraction portion 302 is connected to a non-illustrated suction device such as a vacuum pump, and attract a region between the outer periphery and the central portion of the upper wafer W1 by a suction force generated by the suction device.

In addition, the pins 261, the outer attraction portions 301, and the inner attraction portion 302 described above are members separate from the main body 260, and are formed of, for example, an insulating member.

Further, a plurality of sensors 265 are provided in the main body 260. Each sensor 265 is configured to detect a distance between the upper wafer W1 and the sensor 265 itself. A specific configuration of the sensor 265 will be elaborated later.

The lower chuck 231 has a main body 290 having a diameter equal to or larger than the diameter of the lower wafer W2. Here, the lower chuck 231 is illustrated as having a larger diameter than the lower wafer W2. A top surface of the main body 290 is a facing surface that faces the bottom surface (non-bonding surface W2n) of the lower wafer W2.

A plurality of pins 291 configured to be brought into contact with the bottom surface (non-bonding surface Wn2) of the lower wafer W2 is provided on the top surface of the main body 290. The pins 291 have a diameter of, e.g., 0.1 mm to 1 mm and a height of several tens of μm to several hundreds of μm. The plurality of pins 291 are evenly arranged at a distance of, e.g., 2 mm.

Further, on the top surface of the main body 290, a lower rib 292 is annularly provided outside the plurality of pins 291. The lower rib 292 is formed in an annular shape, and supports the outer periphery of the lower wafer W2 along the entire circumference thereof.

The main body 290 has a plurality of lower suction ports 293. The plurality of lower suction ports 293 are provided in an attraction region surrounded by the lower rib 292. These lower suction ports 293 are connected to a non-illustrated suction device such as a vacuum pump via a non-illustrated suction line.

The lower chuck 231 decompresses the suction region surrounded by the lower rib 292 by evacuating the suction region through the plurality of lower suction ports 293. As a result, the lower wafer W2 placed in the suction region is attracted to and held by the lower chuck 231.

Since the lower rib 292 supports the outer periphery of the bottom surface of the lower wafer W2 along the entire circumference thereof, the lower wafer W2 is properly suctioned including the outer periphery thereof. Thus, the entire surface of the lower wafer W2 can be attracted and held. In addition, since the bottom surface of the lower wafer W2 is supported by the plurality of pins 291, the lower wafer W2 can be easily separated from the lower chuck 231 when the suctioning of the lower wafer W2 is released.

Additionally, the lower chuck 231 is provided with no sensor 265. In other words, the sensor 265 does not exist on the opposite side of the main body 260 with the upper wafer W1 in between. That is, a distance measuring method according to the present exemplary embodiment is different from conventional non-contact type thickness measurement in which two sensors are disposed to face each other with a measurement target therebetween to measure the thickness of the measurement target, for example.

The bonding apparatus 41 according to the exemplary embodiment configured as described above presses the central portion of the upper wafer W1 attracted to and held by the upper chuck 230 with a tip end of the pressing pin 281 to bring it into contact with the lower wafer W2. As a result, a bonding wave is generated between the upper wafer W1 and the lower wafer W2, whereby a bonding region gets expanded from the central portions of the upper and lower wafers W1 and wafer W2 toward the outer peripheries thereof. Finally, the entire bonding surface W1j of the upper wafer W1 and the entire bonding surface W2j of the lower wafer W2 come into contact with each other to thereby form the combined wafer T. At this time, a processing of measuring the progress of the bonding wave by measuring the distance from the sensor 265 to the upper wafer W1 is performed by using the sensor 265. The accurate measurement of the progress of the bonding wave leads to improvement in bonding precision for the combined wafer T.

Here, as a way to accurately measure the progress of the bonding wave, a method of increasing the number of the sensors 265 may be considered. For example, by using an electrostatic capacitance sensor that is smaller than an optical displacement meter or the like, the number of the sensors 265 used to measure the distance to the upper wafer W1 can be increased. If the number of the sensors 265 used to measure the distance to the upper wafer W1 increases, the progress of the bonding wave can be measured accurately. Furthermore, by measuring a distance between the sensor 265 and the combined wafer T after being bonded, a thickness distribution of the combined wafer T can also be accurately measured.

However, in case that the electrostatic capacitance sensor is used as the sensor 265, a measurement target is usually a conductor, and the electrostatic capacitance sensor and the measurement target are electrically connected. However, it has been difficult to meet these requirements in a conventional bonding apparatus.

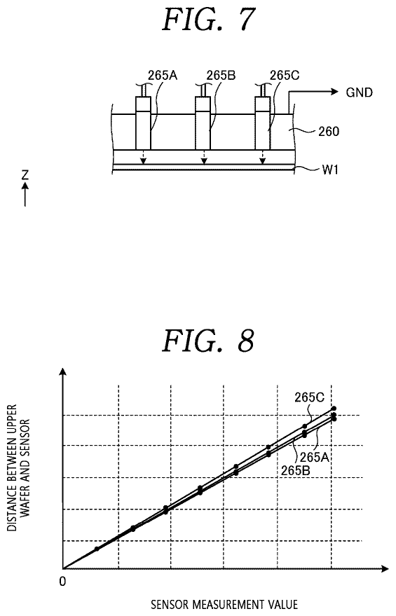

In this regard, the present inventor has found out that if a conductive member is used as the main body 260 of the upper chuck 230 and the sensor 265 is grounded via the main body 260, it is possible to measure the distance between the sensor 265 and the upper wafer W1 even when there is no conduction between the sensor 265 and the upper wafer W1. FIG. 7 is an enlarged schematic diagram of the main body 260 of the upper chuck 230, sensors 265A to 265C, and the upper wafer W1 according to the exemplary embodiment. FIG. 8 is a graph showing variations in measurement values of the sensors 265A to 265C in FIG. 7.

As depicted in FIG. 7, in this experiment, the distance from the main body 260 to the upper wafer W1 is measured by using the three electrostatic capacitance sensors 265A to 265C. The main body 260 is disposed to face the upper wafer W1 in a non-contact manner. The main body 260 is formed of a conductive member, and the sensors 265A to 265C are grounded via the main body 260. Further, an insulating sheet may be provided between the main body 260 and the upper wafer W1 to suppress conduction between the upper wafer W1 and the main body 260.

In FIG. 8, a vertical axis represents the distance between the upper wafer W1 and each of the sensors 265A to 265C. In addition, FIG. 8 shows results of the experiment when the distances between the upper wafer W1 and the sensors 265A to 265C are changed equally, that is, when the main body 260 is moved parallel to the upper wafer W1.

As shown in FIG. 8, as the distance between the upper wafer W1 and the sensors 265A to 265C increases, the measurement values of the sensors 265A to 265C increase.

In this way, as can be seen from the experimental results shown in FIG. 8, if a conductive member is used as the main body 260 of the upper chuck 230 and the sensor 265 is grounded via the main body 260, the distance between the sensor 265 and the upper wafer W1 can be measured.

In view of this, the sensor 265 in the bonding apparatus 41 according to the present exemplary embodiment is grounded via the main body 260. Further, the main body 260 is formed of a conductive member. The conductive member may be a metal material or conductive ceramics, but is not limited thereto. As an example, the main body 260 may be formed of aluminum. Additionally, the main body 260 may be subjected to a surface treatment such as antistatic coating.

Electrostatic capacitance sensors are used as the plurality of sensors 265 provided in the main body 260. As shown in FIG. 6, the plurality of sensors 265 are provided on the bottom surface of the main body 260 along a diametrical direction. Specifically, the bonding wave expands rapidly in a 45-degree direction as compared to a 90-degree direction. The 90-degree direction refers to a direction (directions of 0 degree, 90 degrees, 180 degrees, and 270 degrees) with a period of 90 degrees based on a direction from the center of the upper wafer W1 toward a crystal direction of [0-11] parallel to the front surface of the upper wafer W1. The 45-degree direction refers to a direction (directions of 45 degree, 135 degrees, 225 degrees, and 315 degrees) with a period of 90 degrees based on a direction from the center of the upper wafer W1 toward a crystal direction of parallel to the front surface of the upper wafer W1. The plurality of sensors 265 are arranged along the 90-degree direction and the 45-degree direction.

The area of a facing surface of the main body 260 that faces the upper wafer W1 is equal to or larger than the area of a surface of the upper wafer W1 facing the main body 260. Although the main body 260 and the upper wafer W1 are not in contact with each other, the facing area between the conductive main body 260 and the upper wafer W1 is large, so that the sensor 265 can detect a sufficient electrostatic capacitance for the distance measurement. For this reason, the distance to the upper wafer W1, which is the measurement target, can be measured without establishing electric conduction between the sensor 265 and the upper wafer W1.

The lower chuck 231 may be formed of an insulating (non-conductive) member. For example, if the lower chuck 231 is made of a conductive material, electric conduction would be established between the sensor 265 and the lower chuck 231, which could cause the electrostatic capacitance detected by the sensor 265 to become unstable, resulting in an unstable measurement value. As a resolution, by forming the lower chuck 231 with an insulating member, such a risk can be reduced. The insulating member may be, by way of example, but not limitation, alumina ceramics or silicon nitride.

### <Specific Operation of Bonding System>

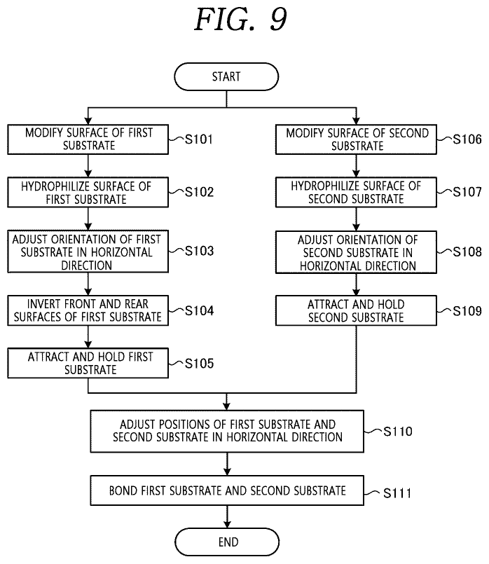

Now, a specific operation of the bonding system 1 according to the exemplary embodiment will be explained with reference to FIG. 9. FIG. 9 is a flowchart illustrating a sequence of a processing performed by the bonding system 1 according to the exemplary embodiment. Various processes shown in FIG. 9 are controlled under the control of the control device 70.

First, the cassette C1 accommodating therein a plurality of upper wafers W1, the cassette C2 accommodating therein a plurality of lower wafers W2, and the empty cassette C3 are placed on the preset placement plates 11 of the carry-in/out station 2. Then, the upper wafer W1 is taken out of the cassette C1 by the transfer device 22, and transferred to the transition device disposed in the third processing block G3.

Next, the upper wafer W1 is transferred to the surface modifying apparatus 30 of the first processing block G1 by the transfer device 61. In the surface modifying apparatus 30, an oxygen gas as a processing gas is excited into plasma under a preset decompressed atmosphere to be ionized. The oxygen ions are radiated to the bonding surface of the upper wafer W1, so that the bonding surface is plasma-processed. As a result, the bonding surface of the upper wafer W1 is modified (process S101).

Subsequently, the upper wafer W1 is transferred to the surface hydrophilizing apparatus 40 of the first processing block G1 by the transfer device 61. In the surface hydrophilizing apparatus 40, while rotating the upper wafer W1 held by the spin chuck, pure water is supplied onto the upper wafer W1. As a result, the bonding surface of the upper wafer W1 is hydrophilized. Further, the bonding surface of the upper wafer W1 is also cleaned by the pure water (process S102).

Next, the upper wafer W1 is transferred to the bonding apparatus 41 of the second processing block G2 by the transfer device 61. The wafer W1 carried into the bonding apparatus 41 is transferred to the position adjusting mechanism 210 via the transition device 200, and the direction of the upper wafer W in the horizontal direction is adjusted by the position adjusting mechanism 210 (process S103).

Thereafter, the upper wafer W1 is delivered from the position adjusting mechanism 210 to the inverting mechanism 220, and the front and rear surfaces of the upper wafer W1 are inverted by the inverting mechanism 220 (process S104). To be specific, the bonding surface W1j of the upper wafer W1 is turned to face downwards. Subsequently, the upper wafer W1 is transferred from the inverting mechanism 220 to the upper chuck 230, and the upper wafer W1 is attracted to and held by the upper chuck 230 (process S105).

In parallel with the processes S101 to S105 upon the upper wafer W1, the lower wafer W2 is also processed. First, the lower wafer W2 is taken out of the cassette C2 by the transfer device 22, and transferred to the transition device disposed in the third processing block G3.

Next, the lower wafer W2 is transferred to the surface modifying apparatus 30 by the transfer device 61, and the bonding surface W2j of the lower wafer W2 is modified (process S106). Thereafter, the lower wafer W2 is transferred to the surface hydrophilizing apparatus 40 by the transfer device 61, and the bonding surface W2j of the lower wafer W2 is hydrophilized and cleaned (process S107).

Afterwards, the lower wafer W2 is transferred to the bonding apparatus 41 by the transfer device 61. The lower wafer W2 carried into the bonding apparatus 41 is transferred to the position adjusting mechanism 210 via the transition device 200. Then, the direction of the lower wafer W2 in the horizontal direction is adjusted by the position adjusting mechanism 210 (process S108).

Thereafter, the lower wafer W2 is transferred to the lower chuck 231, and is attracted to and held by the lower chuck 231 with the notch thereof directed toward a predetermined direction (process S109).

Subsequently, position alignment of the upper wafer W1 held by the upper chuck 230 and the lower wafer W2 held by the lower chuck 231 in the horizontal direction is carried out (process S110). Then, the lower wafer W2 is raised by using the first mover 250 to bond the upper wafer W1 and the lower wafer W2 (process S111). Specifically, after the lower wafer W2 is first raised, the center of the upper wafer W1 is pressed downwards from above by using the pressing pin 281 of the striker 280 into contact with the center of the lower wafer W2, whereby bonding is started between the centers. Afterwards, a bonding wave is generated between the upper wafer W1 and the lower wafer W2, whereby a bonding region gets expanded from the centers of the upper and lower wafers W1 and W2 toward the outer peripheries thereof. Then, the entire bonding surface W1j of the upper wafer W1 and the entire bonding surface W2j of the lower wafer W2 come into contact with each other, so that the upper wafer W1 and the lower wafer W2 are bonded.

In addition, in the process S111, by detecting the distance to the upper wafer W1 through the use of the plurality of sensors 265, the progress of the bonding wave is measured, and a bonding state between the upper wafer W1 and the lower wafer W2 is inspected. As stated above, the plurality of sensors 265 are arranged along the diametrical direction of the upper wafer W1. The bonding apparatus 41 detects the distance between the sensor 265 and the upper wafer W1 at multiple points along the diametrical direction of the upper wafer W1, and can observe a boundary position between the bonding region between the upper wafer W1 and the lower wafer W2 and a non-bonding region located outside the bonding region based on the detected distances.

As described above, in the bonding apparatus 41 according to the exemplary embodiment, the main body 260 of the upper chuck 230 is formed of a conductive member, and the sensor 265 is grounded by the main body 260. With this configuration, the distance to the upper wafer W1 can be measured without establishing electric conduction between the sensor 265 and the upper wafer W1, which is the measurement target. Furthermore, since the upper wafer W1 is a semiconductor, distance measurement can be performed by using the sensor 265 even when the measurement target is not a conductor.

In addition, although the exemplary embodiment has been described for the example where the upper wafer W is the measurement target, the measurement target is not limited thereto. By way of example, the measurement target may be a conductor. In this case as well, measurement of a distance to the measurement target can still be performed without needing to establish electric conduction between the measurement target and the sensor 265.

Further, the present disclosure may have the following configurations.

(1)

A distance measuring device, including:
a first member disposed to face a measurement target, which is a conductor or a semiconductor, in a non-contact manner; and
an electrostatic capacitance sensor provided at the first member, and configured to measure a distance to the measurement target,
wherein the first member is formed of a conductive member, and the electrostatic capacitance sensor is grounded via the first member.

(2)

The distance measuring device described in (1),
wherein the electrostatic capacitance sensor includes multiple electrostatic capacitance sensors.

(3)

The distance measuring device described in (1) or (2),
wherein an area of a facing surface of the first member that faces the measurement target is equal to or larger than an area of a facing surface of the measurement target that faces the first member.

(4)

A distance measuring method, including:
measuring a distance to a measurement target, which is a conductor or a semiconductor, by using a first member disposed to face the measurement target in a non-contact manner and an electrostatic capacitance sensor provided at the first member and configured to measure the distance to the measurement target,
wherein the first member is formed of a conductive member, and the electrostatic capacitance sensor is grounded via the first member.

(5)

A bonding apparatus, including:
a first holder configured to attract and hold a first substrate from above;
a second holder disposed below the first holder, and configured to attract and hold a second substrate from below; and
a pressing member provided at the first holder, and configured to press a central portion of the first substrate,
wherein the first holder includes:
a first member disposed to face the first substrate in a non-contact manner; and
an electrostatic capacitance sensor provided at the first member, and configured to detect a distance to the first substrate, and
wherein the first member is formed of a conductive member, and the electrostatic capacitance sensor is grounded via the first member.

(6)

The bonding apparatus described in (5),
wherein an area of a facing surface of the first member that faces the first substrate is equal to or larger than an area of a facing surface of the first substrate that faces the first member.

(7)

The bonding apparatus described in (5) or (6),
wherein the second holder is formed of an insulating member.

(8)

The bonding apparatus described in any one of (5) to (7),
wherein the electrostatic capacitance sensor includes multiple electrostatic capacitance sensors, and the multiple electrostatic capacitance sensors are arranged along a diametrical direction of the first member, and
wherein the bonding apparatus further includes a controller configured to observe a boundary position between a bonding region in which the first substrate and the second substrate are bonded and a non-bonding region located outside the bonding region by detecting the distance to the first substrate with the multiple electrostatic capacitance sensors.

(9)

A bonding method, including:
attracting and holding a first substrate from above by using a first holder configured to attract and hold the first substrate from above, the first holder including a first member disposed to face the first substrate in a non-contact manner and an electrostatic capacitance sensor provided at the first member and configured to detect a distance to the first substrate;
attracting and holding a second substrate from below by using a second holder disposed below the first substrate and configured to attract and hold the second substrate from below;
pressing a central portion of the first substrate attracted to and held by the first holder, by using a pressing member provided at the first holder and configured to press the central portion of the first substrate; and
detecting the distance to the first substrate by using the electrostatic capacitance sensor,
wherein the first member is formed of a conductive member, and the electrostatic capacitance sensor is grounded via the first member.

(10)

The bonding method described in (9),
wherein the electrostatic capacitance sensor includes multiple electrostatic capacitance sensors, and the multiple electrostatic capacitance sensors are arranged along a diametrical direction of the first member, and
wherein the bonding method further includes:
observing a boundary position between a bonding region in which the first substrate and the second substrate are bonded and a non-bonding region located outside the bonding region based on the distance detected in the detecting of the distance to the first substrate.

It should be noted that the above-described exemplary embodiment is illustrative in all aspects and is not anyway limiting. In fact, the above-described exemplary embodiment can be embodied in various forms. The above-described exemplary embodiment may be omitted, replaced and modified in various ways without departing from the scope and the spirit of claims.

According to the exemplary embodiment, it is possible to carry out the distance measurement by using the electrostatic capacitance sensor even when there is no electrical conduction between the electrostatic capacitance sensor and the measurement target.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A distance measuring device, comprising:
a first member disposed to face a measurement target, which is a conductor or a semiconductor, in a non-contact manner; and
an electrostatic capacitance sensor provided at the first member, and configured to measure a distance to the measurement target,
wherein the first member is formed of a conductive member, and the electrostatic capacitance sensor is grounded via the first member.

2. The distance measuring device of claim 1,
wherein the electrostatic capacitance sensor includes multiple electrostatic capacitance sensors.

3. The distance measuring device of claim 1,
wherein an area of a facing surface of the first member that faces the measurement target is equal to or larger than an area of a facing surface of the measurement target that faces the first member.

4. A bonding apparatus, comprising:
a first holder configured to attract and hold a first substrate from above;
a second holder disposed below the first holder, and configured to attract and hold a second substrate from below; and
a pressing member provided at the first holder, and configured to press a central portion of the first substrate,
wherein the first holder comprises:
a first member disposed to face the first substrate in a non-contact manner; and
an electrostatic capacitance sensor provided at the first member, and configured to detect a distance to the first substrate, and
wherein the first member is formed of a conductive member, and the electrostatic capacitance sensor is grounded via the first member.

5. The bonding apparatus of claim 4,
wherein an area of a facing surface of the first member that faces the first substrate is equal to or larger than an area of a facing surface of the first substrate that faces the first member.

6. The bonding apparatus of claim 4,
wherein the second holder is formed of an insulating member.

7. The bonding apparatus of claim 4,
wherein the electrostatic capacitance sensor includes multiple electrostatic capacitance sensors, and the multiple electrostatic capacitance sensors are arranged along a diametrical direction of the first member, and
wherein the bonding apparatus further comprises a controller configured to observe a boundary position between a bonding region in which the first substrate and the second substrate are bonded and a non-bonding region located outside the bonding region by detecting the distance to the first substrate with the multiple electrostatic capacitance sensors.
